(19) United States
(12) Patent Application Publication
(10) Pub. No.: US 2012/0060907 A1
(43) Pub. Date: Mar. 15, 2012

(54) PHOTOVOLTAIC CELL STRUCTURE AND METHOD INCLUDING COMMON CATHODE

(75) Inventors: Winston V. Schoenfeld, Oviedo, FL (US); Hani Khallaf, El-Minia City (EG)

(73) Assignee: UNIVERSITY OF CENTRAL FLORIDA, Orlando, FL (US)

(21) Appl. No.: 13/173,748

(22) Filed: Jun. 30, 2011

Related U.S. Application Data
(60) Provisional application No. 61/382,192, filed on Sep. 13, 2010.

(51) Int. Cl. H01L 31/06; H01L 31/0224; H01L 31/0216

(52) U.S. Cl. 136/255; 136/256; 438/98; 257/E31.124

(57) ABSTRACT

A back-to-back parallel tandem organic photovoltaic cell structure and a method for fabricating the back-to-back parallel tandem organic photovoltaic cell structure include an aluminum doped zinc oxide material layer (AZO) as a common central cathode within the back-to-back parallel tandem organic photovoltaic cell structure and sandwiched between (and contacting) a pair of lithium fluoride material layers (LiF). The back-to-back parallel tandem organic photovoltaic cell structure and the related method also includes separate and different active material layers further separated from the aluminum doped zinc oxide material layer (AZO) common central cathode and further separated nickel and indium doped tin oxide material layer (Ni-ITO) anodes. An aluminum doped zinc oxide material layer (AZO) and lithium fluoride material layer (LiF) laminate is also contemplated for use in various photovoltaic cell structures.

### CROSS-REFERENCE TO RELATED APPLICATION

This application is related to, and derives priority from, application Ser. No. 61/382,192, filed 13 Sep. 2010 and titled “Three Terminal Structure with Common Cathode, Method, and Applications,” the content of which is incorporated herein fully by reference.

### BACKGROUND

1. Field of the Invention

Embodiments relate generally to photovoltaic cell structures and methods for fabricating photovoltaic cell structures. More particularly, embodiments relate to enhanced performance of photovoltaic cell devices that result from photoillumination operation of photovoltaic cell structures.

2. Description of the Related Art

Organic photovoltaic (OPV) cell devices have recently attracted considerable commercial attention due to their low cost, light weight, ease of fabrication processing and mechanical flexibility. Notwithstanding the foregoing advantages of organic photovoltaic cell devices, acceptance of organic photovoltaic cell devices in the commercial and residential marketplace has nonetheless been limited by photovoltaic performance deficiencies of organic photovoltaic cell devices. In particular, such photovoltaic performance deficiencies may include, but are not necessarily limited to: (1) inefficient charge carrier extraction characteristics; (2) particularly low charge carrier mobility characteristics; and (3) generally narrow photovoltaic absorption ranges.

In turn, the foregoing photovoltaic performance deficiencies limit photoconversion efficiencies of organic photovoltaic cell devices in comparison with photoconversion efficiencies of the most promising silicon based photovoltaic cell devices. In that regard, such a photoconversion efficiency of an organic photovoltaic cell device typically does not reach a 10% photoconversion threshold efficiency that may be required for a successful commercial or residential implementation of an organic photovoltaic cell device.

In an effort to provide enhanced photoconversion efficiencies within organic photovoltaic cell devices, tandem organic photovoltaic cell structures and tandem organic photovoltaic cell devices have recently evolved. Tandem organic photovoltaic cell structures may be fabricated using either a series connection within a pair of individual organic photovoltaic cell structures or a parallel connection within a pair of individual organic photovoltaic cell structures. Tandem organic photovoltaic cell structures that include a parallel connection are generally desirable insofar as within that type of organic photovoltaic cell structure electrical performance characteristics of individual organic photovoltaic cell devices may be individually and independently added.

Since tandem organic photovoltaic cell structures may provide a viable pathway to enhanced electrical performance properties within organic photovoltaic cell devices, desirable are tandem organic photovoltaic cell structures, tandem organic photovoltaic cell devices that derive from operation of the tandem organic photovoltaic cell structures, related methods and related materials that provide for enhanced photovoltaic conversion efficiency of tandem organic photovoltaic cell devices.

### SUMMARY

Embodiments include a photovoltaic cell structure, such as but not limited to a tandem organic photovoltaic cell structure, and a method for fabricating the photovoltaic cell structure, such as but not limited to the tandem organic photovoltaic cell structure.

A back-to-back parallel tandem organic photovoltaic cell structure in accordance with the embodiments includes as a common cathode that separates two anodes within the back-to-back parallel tandem organic photovoltaic cell structure an aluminum doped zinc oxide material layer (AZO) that includes located and formed upon opposite side surfaces of the aluminum doped zinc oxide material layer (AZO) a plurality (i.e., a pair) of lithium fluoride material layers (LiF).

Within the embodiments, the aluminum doped zinc oxide material layer (AZO) has an optical transparency sufficiently high such that incoming radiation whose photovoltaic conversion is desired is not substantially attenuated by the aluminum doped zinc oxide material layer (AZO).

Moreover, within the embodiments, the lithium fluoride material layers provide for an efficient charge transfer with respect to the aluminum doped zinc oxide material layer (AZO) within the organic photovoltaic cell device that results from operation of the organic photovoltaic cell structure.

A particular photovoltaic cell structure in accordance with the embodiments includes an aluminum doped zinc oxide material layer located over a substrate. This particular photovoltaic cell structure also includes at least one lithium fluoride material layer located over the substrate and contacting the aluminum doped zinc oxide material layer.

Another particular photovoltaic cell structure in accordance with the embodiments includes a first transparent conductive oxide material layer anode electrode located over a transparent substrate. This particular photovoltaic cell structure also includes a first active material layer located over the first transparent conductive oxide material layer anode electrode. This particular photovoltaic cell structure also includes an aluminum doped zinc oxide common cathode electrode material layer sandwiched between and contacting a pair of lithium fluoride material layers and located over the first active material layer. This particular photovoltaic cell structure also includes a second active material layer located over the common cathode electrode material layer. This particular photovoltaic cell structure also includes a second transparent conductive oxide material layer anode electrode located over the second active material layer.

A particular method for fabricating a photovoltaic cell structure includes forming over a transparent substrate a laminate that includes an aluminum doped zinc oxide material layer contacting at least one lithium fluoride material layer.

Another particular method for fabricating a photovoltaic cell structure includes forming a first transparent conductive oxide material layer over a transparent substrate. This particular method also includes forming a first active material layer over the first transparent conductive oxide material layer. This particular method also includes forming a first lithium fluoride material layer over the first active material layer. This particular method also includes forming an aluminum doped zinc oxide material layer upon the first lithium fluoride material layer. This particular method also includes forming a second lithium fluoride material layer upon the aluminum doped zinc oxide material layer. This particular method also includes forming a second active material layer over the second lithium fluoride material layer. This particular method also includes forming a second transparent conductive oxide material layer over the second active material layer.

Within the context of the embodiments and the claimed invention, use of the terminology “over” with respect to material layers is intended to indicate that one material layer is above another material layer with respect to a substrate, but not necessarily contacting the other material layer.

Within the context of the embodiments and the claimed invention, use of the terminology “upon” with respect to material layers is intended to indicate that one material layer is above and contacting the other material layer.

### BRIEF DESCRIPTION OF THE DRAWING

The objects, features and advantages of the embodiments are understood within the context of the Detailed Description of the Embodiments, as set forth below. The Detailed Description of the Embodiments is understood within the context of the accompanying drawings, that form a material part of this disclosure, wherein:

FIG. 1 shows a schematic cross-sectional diagram of a back-to-back parallel tandem organic photovoltaic cell structure in accordance with the embodiments.

FIG. 2 shows a schematic energy band diagram illustrating a portion of the back-to-back parallel tandem organic photovoltaic cell structure whose schematic cross-sectional diagram is illustrated in FIG. 1.

### DETAILED DESCRIPTION OF THE EMBODIMENTS

The embodiments, which include a back-to-back parallel tandem organic photovoltaic cell structure and a method for fabricating the back-to-back parallel tandem organic photovoltaic cell structure, are understood within the context of the description set forth below. The description set forth below is understood within the context of the drawings described above. Since the drawings are intended for illustrative purposes, the drawings are not necessarily drawn to scale.

Most generally, the embodiments include within the context of a back-to-back parallel tandem organic photovoltaic cell structure and related method for fabricating the back-to-back parallel tandem organic photovoltaic cell structure an aluminum doped zinc oxide material layer (AZO) as a common cathode within the back-to-back parallel tandem organic photovoltaic cell structure. Such an aluminum doped zinc oxide material layer (AZO) is sandwiched between a pair of lithium fluoride material layers (LiF) and separates a proximal organic photovoltaic cell structure from a distal organic photovoltaic cell structure within the back-to-back parallel tandem organic photovoltaic cell structure.

While the embodiments illustrate the invention within the context of such a back-to-back parallel tandem organic photovoltaic cell structure, neither the embodiments, nor the invention as claimed below, is necessarily intended to be so limited. Rather, the embodiments are also intended to include any of several types of photovoltaic cell structures that include as preferably but not necessarily an electrode structure an aluminum doped zinc oxide material layer (AZO) having laminated to at least one side of the aluminum doped zinc oxide material layer (AZO) a lithium fluoride material layer (LiF).

Such other types of photovoltaic cell structures may include, but are not necessarily limited to, single photovoltaic cell structures and multiple photovoltaic cell structures, whether organic photovoltaic or not, that include tandem photovoltaic cell structures of a back-to-back parallel structure and a series structure.

The description that follows will first describe structural features and operational features of an anticipated back-to-back parallel tandem organic photovoltaic cell structure in accordance with the embodiments. The description that follows will next describe anticipated fabrication methodology for fabricating the anticipated back-to-back parallel tandem organic photovoltaic cell structure in accordance with the embodiments.

### Structural Features and Operational Features of Anticipated Back-to-Back Parallel Tandem Organic Photovoltaic Cell Structure.

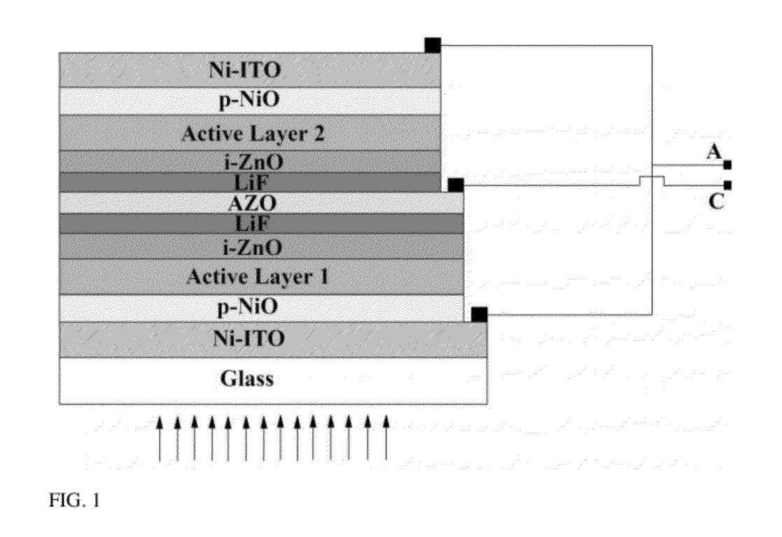

Drawing FIG. 1 in accordance with the embodiments shows a schematic cross-sectional diagram of an anticipated back-to-back parallel tandem organic photovoltaic cell structure in accordance with the embodiments. The anticipated back-to-back parallel tandem organic photovoltaic cell structure includes a transparent substrate (designated as glass) upon and over which is sequentially layered a plurality of layers that comprise the anticipated back-to-back parallel tandem organic photovoltaic cell structure in accordance with the embodiments. Within the anticipated back-to-back parallel tandem organic photovoltaic cell structure in accordance with the embodiments as illustrated within FIG. 1, an aluminum doped zinc oxide material layer (AZO) comprises a central common cathode for a pair of parallel tandem organic photovoltaic cell structures that is arranged back-to-back within the parallel tandem organic photovoltaic cell structure.

As is further illustrated within the schematic cross-sectional diagram of FIG. 1, located and formed laminated to each side of the aluminum doped zinc oxide material layer (AZO) is a lithium fluoride material layer (LiF). Located and formed laminated to the other side of each of the lithium fluoride material layers (LiF) is a zinc oxide material layer (i-ZnO). Located and formed laminated to the other side of each of zinc oxide material layers (i-ZnO) are distinct and separate active material layers (Active Layer 1 and Active Layer 2). Located and formed laminated to other side of the distinct and separate active material layers (Active Layer 1 and Active Layer 2) is a nickel oxide material layer (p-NiO). Finally, located and formed laminated to the other side of each of the nickel oxide material layers (p-NiO) is a nickel and indium doped tin oxide material layer (Ni-ITO), which in an aggregate serve as anode layers within each of the individual organic photovoltaic cell structures within the back-to-back parallel tandem organic photovoltaic cell structure of FIG. 1 in accordance with the embodiments.

Thus, disclosed within the context of the embodiments and also within the context of FIG. 1, is a three terminal back-to-back parallel tandem organic photovoltaic cell structure with an aluminum doped zinc oxide material layer (AZO) as a common cathode. An aluminum doped zinc oxide material used for the common cathode within the context of an organic photovoltaic cell structure in accordance with the embodiments may be highly transparent (i.e., having a transparency (i.e., transmittance at a relevant, typically solar, wavelength spectrum) preferably at least about 90 percent at a thickness from about 200 to about 250 nanometers and more preferably having a transparency from about 90 to about 95 percent) and highly conducting (i.e., having a sheet resistance no greater than about 10 ohms per square. Typically and preferably, the aluminum doped zinc oxide material layer (AZO) has an aluminum content appropriate to fulfill the foregoing optical transparency and sheet resistance characteristics. Thus, an aluminum doped zinc oxide material layer (AZO) generally fulfills the requirements of a transparent conducting oxide material layer that may be used as a conductive oxide material layer cathode electrode within an organic photovoltaic cell structure.

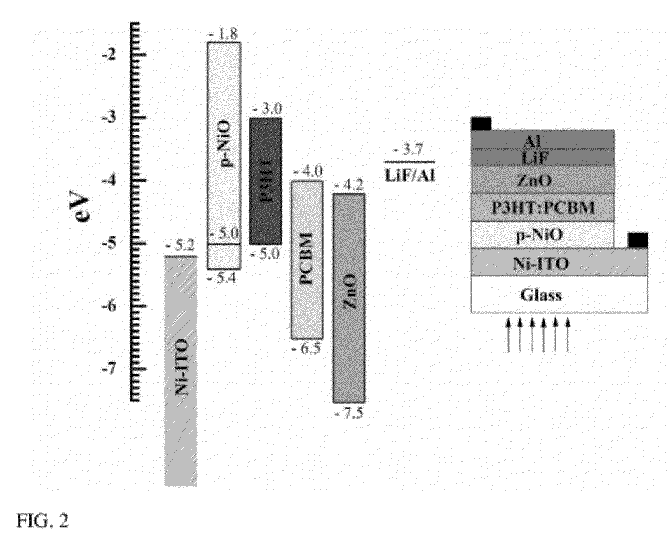

Moreover, as is illustrated within the energy band diagram of FIG. 2, a conduction band minimum (CBM) of a zinc oxide material (ZnO) is located at −4.2 eV. Thus, for a heavily doped aluminum doped zinc oxide material layer (AZO), one may plausibly assume that a Fermi level will be reasonably close to −4.2 eV, which matches the Fermi level of an aluminum material layer (Al) electrode that may otherwise commonly be used as a cathode electrode for an organic photovoltaic cell structure where a high level of optical transparency of the cathode electrode that comprises aluminum material layer (Al) is not needed.

Within the context of a common cathode that comprises an aluminum doped zinc oxide material layer (AZO), the presence of a very thin layer (i.e., approximately 1 nanometer, and more generally from about 0.5 to about 1.0 nanometer) of a lithium fluoride material layer (LiF) is intended to provide ohmic contact for electrons from both of the back-to-back parallel tandem organic photovoltaic cell structures within the back-to-back parallel tandem organic photovoltaic cell structure in accordance with the embodiments. Moreover, the lithium fluoride material layers (LiF) located and formed laminated to both sides of the aluminum doped zinc oxide material layer (AZO) are desirable insofar as the lowest unoccupied molecular orbital (LUMO) of an active material layer within an organic photovoltaic cell structure (i.e., such as PCBM active material layer within an organic photovoltaic cell structure) is about −4.0 eV, as is also illustrated, for example, in FIG. 2.

As a result, it is desirable that the work function of a cathode material layer within a back-to-back parallel tandem organic photovoltaic cell structure in accordance with the embodiments should be less negative than about −4.0 eV to ensure an ohmic contact for electrons within the back-to-back parallel tandem organic photovoltaic cell structure.

An effective work function for a lithium fluoride (LiF) material layer/aluminum material layer (Al) laminated composite cathode has been reported, for example, to be about −3.7 eV (see, e.g., Mihailetchi et al., J. Appl. Phys. 94, 6849 (2003)), as is also illustrated in FIG. 2. Since such a lithium fluoride material layer (LiF)/aluminum material layer (Al) laminate composite cathode may have a thickness of one nanometer or less, no significant incoming light absorption is expected to take place in a lithium fluoride material layer (LiF) clad aluminum doped zinc oxide material layer (AZO) common cathode within a back-to-back parallel tandem organic photovoltaic cell structure in accordance with the embodiments, and as illustrated within the schematic cross-sectional diagram of FIG. 1.

Within the schematic cross-sectional diagram of FIG. 1, the zinc oxide material layers (i-ZnO) are intended as electron transport and hole blocking material layers that provide for enhanced electron transport efficiency for transport of electron charge carriers to the aluminum doped zinc oxide material layer (AZO) cathode electrode while inhibiting hole charge carrier transport to the aluminum doped zinc oxide material layer (AZO) cathode electrode. Some particular bandgap characteristics of the zinc oxide material layers (i-ZnO) are described below.

As is also shown within the schematic cross-sectional diagram FIG. 1, the proposed and anticipated back-to-back parallel tandem organic photovoltaic cell structure in accordance with the embodiments is also intended to be based on two back-to-back bulk heterojunction (BHJ) organic photovoltaic cell structures that utilize two bulk heterojunction (BHJ) material compositions that exhibit complementary absorption bands. The two bulk heterojunction (BHJ) material compositions of complementary absorption bands are intended as encompassed by Active Layer 1 and Active Layer 2. For example, and without limitation, one of the two bulk heterojunction (BHJ) material compositions within Active Layer 1 and Active Layer 2 may comprise a bulk heterojunction material composition such as but not limited to a PCPDTBT:PCBM bulk heterojunction material composition, and the other one of the two bulk heterojunction material compositions within Active Layer 1 and Active Layer 2 may comprise a bulk heterojunction (BHJ) material composition such as but not limited to a P3HT:PCBM bulk heterojunction material composition.

Within the back-to-back parallel tandem organic photovoltaic cell structure whose schematic cross-sectional diagram is illustrated in FIG. 1, the nickel oxide material layers (p-NiO), which do not include an indium dopant) are intended as hole charge carrier transport facilitating and electron charge carrier blocking layers. Typically and preferably the nickel oxide material layers (p-NiO) are anticipated to be formed to a generally conventional thicknesses. Additional bandgap characteristics of the nickel oxide material layers (p-NiO) are also described below.

Finally, within the back-to-back parallel tandem organic photovoltaic cell structure whose schematic cross-sectional diagram is illustrated in FIG. 1, the nickel and indium doped tin oxide material layers (Ni-ITO) are anticipated to be used as anode electrode layers for both organic photovoltaic cell structures within the back-to-back parallel tandem organic photovoltaic cell structure in accordance with the embodiments. A content of nickel doping within such a nickel and indium doped tin oxide material layer will increase (i.e., make more negative) a work function of the nickel and indium doped tin oxide material layer (to provide a work function at least as negative as about −5.0 eV, more typically in a range from about −5.0 to about −5.4 eV and optimally about −5.2 eV) in comparison with an indium doped tin oxide material layer (i.e., which will typically have a work function about −4.7 eV) to match the highest occupied molecular orbital (HOMO) of a conjugated polymer material within either the Active Layer 1 or the Active Layer 2.

Conjugated polymers that are commonly used for organic photovoltaic applications have a HOMO level located between −5.0 eV and −5.3 eV (i.e., below) vacuum level. With the proper Ni-doping of ITO to provide the nickel and indium doped tin oxide material layers (Ni-ITO), the work function can be adjusted and manipulated to match the level of −5.0 eV to −5.3 eV (i.e., below) the vacuum level.

As is illustrated within the schematic cross-sectional diagram of FIG. 1, a nickel oxide material layer (p-NiO) will be used as a hole transport layer and an electron blocking layer (EBL) for both photovoltaic sub-cell structures within the back-to-back parallel tandem photovoltaic cell structure in accordance with the embodiments. As is illustrated within the schematic band gap diagram of FIG. 2, the embodiments consider that p-type doped nickel oxide material layer (p-NiO) may have a valence band maximum (VBM) of about −5.4 eV and a conduction band minimum (CBM) of about −1.8 eV (e.g., about 2.2 eV above the lowest unoccupied molecular orbital (LUMO) level of a PCBM material).

Moreover, the intrinsic zinc oxide material layers (i-ZnO) that are illustrated in FIG. 1 are intended as hole blocking layers (HBL) on the other side of the pertinent active layers Active Layer 1 and Active Layer 2. As is illustrated within the schematic band-gap diagram of FIG. 2, an intrinsic (i.e., undoped) zinc oxide material has a valence band maximum (VBM) of about −7.5 eV (close to 2.5 eV below a highest occupied molecular orbital (HOMO) level of a conjugated polymer, such as but not limited to a P3HT conjugated polymer).

Both nickel oxide material layers (p-NiO) and the zinc oxide material layers (i-ZnO) are generally required to be relatively resistive to avoid formation of any short circuits/shunts and thereby increase the shunt resistance of a back-to-back parallel tandem organic photovoltaic cell device that is derived from photoillumination operation of the back-to-back parallel tandem organic photovoltaic cell structure in accordance with the embodiments. The foregoing resistance characteristics of the nickel oxide material layers (p-NiO) and zinc oxide material layers (i-ZnO) is intended to ensure effective charge separation within the photovoltaic sub-cells within the back-to-back parallel tandem organic photovoltaic cell structure in accordance with the embodiments. The back-to-back parallel tandem organic photovoltaic cell structure in accordance with the embodiments is intended to include a highly transparent aluminum doped zinc oxide material layer (AZO) common cathode for the back-to-back parallel tandem organic photovoltaic cell structure and also should ensure a desirable insulation between the two photovoltaic sub-cells within the back-to-back parallel tandem organic photovoltaic cell structure, so the two photovoltaic sub-cells may function independently.

With the proposed structure of the back-to-back parallel tandem organic photovoltaic cell structure as illustrated within the schematic cross-sectional diagram of FIG. 1, both photovoltaic sub-cells are anticipated to function more efficiently incident to the presence of the zinc oxide material layers (i-ZnO) hole blocking layers (HBL) and nickel oxide material layers (p-NiO) electron blocking layers (EBL), as well as the better control of the work function of the anode, through Ni-doping. The anticipated back-to-back parallel tandem organic photovoltaic cell structure whose schematic cross-sectional diagram is illustrated in FIG. 1 is intended as a generally universal tandem photovoltaic cell structure, which is intended to be employed with different bulk heterojunction (BHJ) materials compositions photovoltaic sub-cells regardless of a conjugated polymer that is being used within a particular bulk heterojunction (BHJ) material composition (i.e., within either Active Layer 1 or Active Layer 2).

### Anticipated Fabrication Methodology for Back-to-Back Parallel Tandem Organic Photovoltaic Cell Structure

The back-to-back parallel tandem organic photovoltaic cell structure in accordance with the embodiments as illustrated in FIG. 1 is anticipated to be fabricated using methods and materials that are otherwise generally conventional in the organic photovoltaic cell structure design and fabrication art, and more generally the electronics and microelectronics design and fabrication art.

For example, the substrate as is illustrated in the FIG. 1 (i.e., which is designated as a glass substrate) is anticipated to comprise any substrate material that is transparent with respect to incoming radiation (i.e., which will typically comprise incoming solar radiation) that is desired to be photovoltaically transformed into electricity. Such anticipated alternative substrate materials may include, but are not limited to, glass substrate materials of various varieties and dopant compositions, quartz substrate materials and certain plastic substrate materials having an appropriate optical transparency and optical clarity. According to an illustrative aspect, the substrate is anticipated to comprise a glass substrate, such as but not limited to a tempered glass substrate.

As discussed above, the nickel and indium doped tin oxide material layer (Ni-ITO) anodes will include a nickel component that provides a work function in a range from at least about (or alternatively more negative than about, or further alternatively no more positive than about) −5.0 eV to about −5.4 eV, more particularly from about −5.1 eV to about −5.3 eV and most particularly about −5.2 eV, so that the embodiments provide an enhanced hole extraction, transfer and collection ability of the organic photovoltaic cell device of FIG. 1 with respect to the nickel and indium doped tin oxide material layer (Ni-ITO) anode.

Also in accordance with the disclosure above, the nickel and indium doped tin oxide material layer (Ni-ITO) anodes are anticipated to be formed using any of several methods that are also otherwise generally conventional in the electronics and microelectronics design and fabrication art, if not necessarily the organic photovoltaic cell design and fabrication art. Included but not limiting among these anticipated methods are chemical vapor deposition (CVD) methods and physical vapor deposition (PVD) methods. Further included within the context of physical vapor deposition (PVD) methods are thermal evaporation methods and sputtering methods, which may include, but are also not limited to: (1) purely physical sputtering methods (i.e., which are typically intended to physically remove material from a target and deposit the material removed from the target compositionally unchanged upon a substrate); and (2) reactive sputtering methods (i.e., which are typically differentiated from purely physical sputtering methods by inclusion of a chemical reaction that provides a chemical difference between a sputter target material that is sputtered and a deposited material layer deposited from the sputter target material). Illustratively, the embodiments anticipate use of a physical sputtering method that uses a prefabricated nickel and indium doped tin oxide material target having a composition desirable within the nickel and indium doped tin oxide material layer (Ni-ITO) anode as illustrated in FIG. 1.

As is discussed above, the nickel and indium doped tin oxide material layer (Ni-ITO) anode comprises a nickel content that provides a work function with ranges that may center at −5.2 eV, so that the nickel and indium doped tin oxide material layer (Ni-ITO) anode may provide the enhanced and optimized photovoltaic performance properties within an organic photovoltaic cell device in accordance with the embodiments. As noted above, the nickel and indium doped tin oxide material layer (Ni-ITO) anode is anticipated to be formed using a physical sputtering method that uses argon or other inert gas ions as a sputtering medium to provide the nickel and indium doped tin oxide material layer (Ni-ITO) anode of appropriate composition.

The bulk heterojunction (BHJ) organic photovoltaic material layers that are designated as Active Layer 1 and Active Layer 2, the p-nickel oxide material layers (p-NiO), the zinc oxide material layers, the lithium fluoride material layers (LiF) and the aluminum doped zinc oxide material layer (AZO) are each also anticipated to be formed using methods and materials that are otherwise considered to be generally conventional for forming those material layers.

The p-nickel oxide material layers (p-NiO) (i.e., which do not include an indium dopant) are anticipated to be located and formed laminated to the nickel and indium doped tin oxide material layer (Ni-ITO) anodes using methods that are noted above, and in particular using a chemical vapor deposition (CVD) method or alternatively a physical vapor deposition (PVD) method. The p dopant (i.e., p-type dopant) that is included within the p-nickel oxide material layers (p-NiO) may be anticipated to be included within a sputtering target that is used for forming the p-nickel oxide material layers (p-NiO), if the p-nickel oxide material layers (p-NiO) are formed using a sputtering method. Alternatively, the p dopant is anticipated to be co-deposited within a chemical vapor deposition (CVD) method. Further alternatively, the p dopant is anticipated to be subsequently incorporated into an otherwise undoped nickel oxide material layer located and formed laminated to the nickel and indium doped tin oxide material layer (Ni-ITO) anodes via a method such as but not limited to an ion implantation method or a thermal diffusion method. Typically the p-nickel oxide material layers (p-NiO) are anticipated to include a p dopant such as but not limited to a boron dopant, at a generally conventional concentration. Typically and preferably, the p-nickel oxide material layers (p-NiO) are anticipated to have a generally conventional thickness.

The bulk heterojunction (BHJ) organic photovoltaic material layers designated as Active Layer 1 and Active Layer 2 are anticipated to comprises an otherwise generally conventional compositions (i.e., as suggested above P3HT and PCBM or PCPDTBT and PCBM) organic photovoltaic material components that are generally included at a generally conventional molar ratio concentration. The particular organic photovoltaic material components are anticipated to be deposited laminated to the p-nickel oxide material layers (p-NiO) using any coating method that is otherwise generally conventional in the organic photovoltaic cell design and fabrication art, and in particular a coating method such as but not limited to a spin coating method. Illustratively, the bulk heterojunction (BHJ) organic photovoltaic material layers designated as Active Layer 1 and Active Layer 2 are anticipated to be located and formed laminated to the p-nickel oxide material layers (p-NiO) to a generally conventional thickness using a spin coating method that uses a solvent solution.

The zinc oxide material layers (i-ZnO) are anticipated to be located and formed laminated to the bulk heterojunction (BHJ) organic photovoltaic material layers (designated as Active Layer 1 or Active Layer 2) using any of several methods that are otherwise generally conventional in the organic photovoltaic cell structure design and fabrication art, or alternatively the electronics and microelectronics design and fabrication art. Such methods may include, but are not necessarily limited to, chemical vapor deposition (CVD) methods and physical vapor deposition (PVD) methods. More particularly, the intrinsic undoped zinc oxide material layers (i-ZnO) are preferably anticipated to be located and formed laminated to the bulk heterojunction material layers (BHJ) designated as Active Layer 1 and Active Layer 2 while using a sputtering method, such as a non-reactive physical sputtering method, to provide the zinc oxide material layers (i-ZnO) of a generally conventional thickness.

Similarly with foregoing layers within the back-to-back parallel tandem organic photovoltaic cell structure whose schematic diagram is illustrated in FIG. 1, the lithium fluoride material layers (LiF) are also anticipated to be formed using any of several methods, including but not limited to chemical vapor deposition (CVD) methods and physical vapor deposition (PVD) methods.

Finally, the aluminum doped zinc oxide material layer (AZO), which serves as the common cathode within the back-to-back parallel tandem organic photovoltaic cell structure of FIG. 1, is also anticipated to be formed using any of several methods that are otherwise generally conventional in the organic photovoltaic cell design and fabrication art, or alternatively the electronic or microelectronics design and fabrication art. Such an aluminum doped zinc oxide material layer (AZO) is anticipated to be formed using physical vapor deposition methods, such as but not limited to sputtering methods and evaporative methods, although thermal evaporation methods are generally common.

The organic photovoltaic cell structure whose schematic cross-sectional diagram is illustrated in FIG. 1 is anticipated to be fabricated using a sequence of deposition methods that is otherwise generally conventional in the organic photovoltaic cell structure design and fabrication art. To that end, advantageously, the organic photovoltaic cell structure of FIG. 1 is anticipated to be fabricated using single individually separated fabrication tools, or alternatively a single fabrication tool with multiple deposition sources or deposition chambers, all maintained under vacuum so that sequentially deposited layers of the organic photovoltaic cell structure of FIG. 1 may be deposited sequentially absent exposure of the organic photovoltaic cell structure to atmosphere that might cause for interfacial modification and contamination of the back-to-back parallel tandem organic photovoltaic cell structure of FIG. 1.

The foregoing embodiments of the invention are illustrative of the invention rather than limiting of the invention. To that end, revisions and modifications may be made to methods, materials, structures and dimensions of an organic photovoltaic cell structure or related method in accordance with the embodiments while still providing an organic photovoltaic cell structure and related method in accordance with the invention, further in accordance with the accompanying claims.

As is understood by a person skilled in the art, within the context of the above disclosure, all references, including publications, patent applications and patents cited herein are hereby incorporated by reference in their entireties to the extent allowed, and to the same extent as if each reference was individually and specifically indicated to be incorporated by reference and was set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is some other element intervening.

The recitation of ranges of values herein is merely intended to serve as an efficient method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate embodiments of the invention and does not impose a limitation on the scope of the invention unless otherwise indicated.

No language in the specification should be construed as indicating any non-claimed element as essential to the practice of the invention.

It will be thus further apparent to those skilled in the art that various modifications and variations can be made to the present invention without departing from the spirit and scope of the invention. There is no intention to limit the invention to the specific form or forms disclosed, but on the contrary, the intention is to cover all modifications, alternative constructions and equivalents falling within the spirit and scope of the invention, as defined in the appended claims. Thus, it is intended that the present invention cover the modifications and variations of this invention provided they come within the scope of the appended claims and their equivalents.

What is claimed is:

1. A photovoltaic cell structure comprising:
an aluminum doped zinc oxide material layer located over a substrate; and
at least one lithium fluoride material layer located over the substrate and contacting the aluminum doped zinc oxide material layer.

2. The photovoltaic cell structure of claim 1 wherein:
the aluminum doped zinc oxide material layer has an optical transparency at least about 90 percent;
the aluminum doped zinc oxide material layer has a thickness from about 200 to about 250 nanometers; and
the lithium fluoride material layer has a thickness from about 0.5 to about 1.0 nanometers.

3. The photovoltaic cell structure of claim 1 wherein the photovoltaic cell structure comprises a single photovoltaic cell structure.

4. The photovoltaic cell structure of claim 1 wherein the photovoltaic cell structure comprises a tandem photovoltaic cell structure.

5. The photovoltaic cell structure of claim 4 wherein:
the tandem photovoltaic cell structure comprises a back-to-back parallel tandem photovoltaic cell structure;
the aluminum doped zinc oxide material layer comprises a common cathode within the back-to-back parallel tandem photovoltaic cell structure; and
the back-to-back parallel tandem photovoltaic cell structure includes two lithium fluoride material layers located over the substrate and contacting opposite sides of the aluminum doped zinc oxide material layer.

6. The photovoltaic cell structure of claim 5 further comprising:
a pair of active material layers having complementary absorption characteristics located over the substrate and sandwiching the pair of lithium fluoride material layers; and
a pair of anode material layers located over the substrate and sandwiching the pair of active material layers.

7. The photovoltaic cell structure of claim 6 further comprising:
a pair of zinc oxide material layers located interposed between the pair of lithium fluoride material layers and the pair of active material layers; and
a pair of nickel oxide material layers located interposed between the pair of active material layers and the pair of anode material layers.

8. A photovoltaic cell structure comprising:
a first transparent conductive oxide material layer anode electrode located over a transparent substrate;
a first active material layer located over the first transparent conductive oxide material layer anode electrode;
an aluminum doped zinc oxide common cathode electrode material layer sandwiched between and contacting a pair of lithium fluoride material layers and located over the first active material layer;
a second active material layer located over the common cathode electrode material layer; and
a second transparent conductive oxide material layer anode electrode located over the second active material layer.

9. The photovoltaic cell structure of claim 8 wherein:
the aluminum doped zinc oxide common cathode electrode material layer has an optical transparency at least about 90 percent;
the aluminum doped zinc oxide common cathode electrode material layer has a thickness from about 200 to about 250 nanometers; and
the lithium fluoride material layers have a thickness from about 0.5 to about 1.0 nanometers.

10. The photovoltaic cell structure of claim 8 wherein each of the first transparent conductive oxide material layer anode electrode and the second transparent conductive oxide material layer anode electrode comprises a nickel and indium doped tin oxide material.

11. The photovoltaic cell structure of claim 8 wherein:
one of the first active material layer and the second active material layer comprises a PCPDTBT:PCBM active material composition; and
the other of the first active material layer and the second active material layer comprises a P3HT:PCBM active material composition.

12. The photovoltaic cell structure of claim 8 further comprising a pair of zinc oxide material layers located interposed between the lithium fluoride material layers and the active material layers.

13. The photovoltaic cell structure of claim 8 further comprising a pair of nickel oxide material layers absent an indium dopant located interposed between the transparent conductive oxide material layer anode electrodes and the active material layers.

14. A method for fabricating a photovoltaic cell structure comprising:
forming over a transparent substrate a laminate that includes an aluminum doped zinc oxide material layer contacting at least one lithium fluoride material layer.

15. The method of claim 14 wherein the laminate includes the aluminum doped zinc oxide material layer contacting and sandwiched between a pair of lithium fluoride material layers.

16. A method for fabricating a photovoltaic cell structure comprising:
forming a first transparent conductive oxide material layer over a transparent substrate;
forming a first active material layer over the first transparent conductive oxide material layer;
forming a first lithium fluoride material layer over the first active material layer;
forming an aluminum doped zinc oxide material layer upon the first lithium fluoride material layer;
forming a second lithium fluoride material layer upon the aluminum doped zinc oxide material layer;
forming a second active material layer over the second lithium fluoride material layer; and
forming a second transparent conductive oxide material layer over the second active material layer.

17. The method of claim 16 wherein the forming the first transparent conductive oxide material layer and the forming the second conductive oxide material layer forms a nickel and indium doped transparent conductive oxide material.

18. The method of claim 16 further comprising:
forming a first nickel oxide material layer upon the first transparent conductive oxide material layer prior to forming the first active material layer over the first transparent conductive oxide material layer; and
forming a second nickel oxide material layer over the second active material layer prior to forming the second transparent conductive oxide material layer over the second active material layer, where the second transparent conductive oxide material layer is formed upon the second nickel oxide material layer.

19. The method of claim 18 wherein neither the first nickel oxide material layer nor the second nickel oxide material layer comprises an indium dopant.

20. The method of claim 16 further comprising:
forming a first zinc oxide material layer over the first active material layer prior to forming the first lithium fluoride material layer over the first active material layer; and
forming a second zinc oxide material layer over the second lithium fluoride material layer prior to forming the second active material layer over the second lithium fluoride material layer.
